(19) United States
(12) Patent Application Publication
(10) Pub. No.: US 2024/0186943 A1
(43) Pub. Date: Jun. 6, 2024

(54) DC POWERED SOLAR TRACKER CONTROLLER WITH HEATED BATTERY

(71) Applicant: OMCO Solar, LLC, Phoenix, AZ (US)

(72) Inventors: MATT KESLER, Phoenix, AZ (US); Lepolve Varpilah, Queen Creek, AZ (US); Nicholas Salvatore Sava, Phoenix, AZ (US); Randy Lee Meder, Buckeye, AZ (US)

(21) Appl. No.: 18/527,134

(22) Filed: Dec. 1, 2023

Related U.S. Application Data
(60) Provisional application No. 63/429,849, filed on Dec. 2, 2022.

(51) Int. Cl. H02S 20/32; G01S 3/786; H01L 31/0475; H01M 10/48; H02S 40/38

(52) U.S. Cl. CPC H02S 20/32; G01S 3/7861; H01L 31/0475; H01M 10/486; H02S 40/38

(57) ABSTRACT

A DC powered solar tracker controller for controlling an angle of inclination of a table of an associated solar tracker assembly. The controller includes controller electronics and a motor driver selectively energized to actuate the drive mechanism and thereby pivot the table of the associated solar tracker assembly. The controller further includes a rechargeable battery for powering controller electronics, the rechargeable battery charged by a controller power source, and a heating element controlled by controller electronics. The heating element is disposed in proximity to the outer surface of the rechargeable battery. The controller also includes a temperature sensor electrically coupled to the controller electronics, the temperature sensor disposed in proximity to the rechargeable battery. The controller electronics monitors the temperature sensor and, when the temperature of the rechargeable battery is within a predetermined range, the controller electronics actuates the heating element to provide heat to the rechargeable battery.

### CROSS REFERENCE TO RELATED APPLICATIONS

The following application claims priority under 35 U.S.C. § 119(e) to co-pending U.S. Provisional Patent Application Ser. No. 63/429,849, filed Dec. 2, 2022, entitled DC Powered Solar Tracker Controller With Heated Battery. The above-identified U.S. provisional patent application is incorporated by reference herein in its entirety for any and all purposes.

### TECHNICAL FIELD

The present disclosure relates to a DC powered solar tracker controller for controlling an angle of inclination of a table of an associated solar tracker assembly and, more specifically, a DC powered solar tracker controller having a heated, rechargeable battery which allows for operation of the solar tracker controller and, specifically, providing power to operate electronics of the solar tracker controller, in cold climate conditions.

### BACKGROUND

Large scale solar tracker installations may include hundreds or thousands of horizontal, single axis solar tracker assemblies or solar tracker systems on an installation site. Each solar tracker assembly includes a pivoting or rotatable table which is driven by a drive mechanism such that the solar tracker assembly table is rotated or pivoted through a predetermined angle of inclination range to track the position of the sun as the sun moves across the sky from east to west during daylight hours. The table of each solar tracker assembly includes a torque tube beam, which may be hundreds of feet in length and is oriented in a north-south direction. The torque tube beam supports a plurality of photovoltaic modules which are affixed along an extent of the torque tube beam via a plurality of mounting brackets. The torque tube beam, in turn, is rotatably supported by a plurality of rotatable bearing assemblies positioned at spaced apart locations along the torque tube beam.

The drive mechanism of the solar tracker assembly provides for precise pivoting or rotational movement of the table and, thereby, the angle of inclination of the table. The drive mechanism, in turn, operates under the control of a solar tracker controller associated with the solar tracker assembly. During daylight time periods or daylight hours, the solar tracker controller, via the drive mechanism, controls the angle of inclination of the table of its associate solar tracker assembly to point the upper surfaces of the plurality of photovoltaic modules at the sun as the sun moves across the sky from east to west. At night, that is, non-daylight hours, the solar tracker controller, via the drive mechanism, moves the table angle of inclination to a night stow position. Under certain abnormal weather conditions, such as windy conditions, overcast conditions, or a snow condition wherein snow has accumulated on the upper surfaces of the plurality of photovoltaic modules, the solar tracker controller will change the table angle of inclination to protect the plurality of photovoltaic modules from potential damage and/or increase energy output. For example, under a snow condition, the solar tracker controller may direct the drive mechanism to execute a snow dump pivot routine of the table to clear snow from upper surfaces of the plurality of photovoltaic modules during or after a snowfall. During high wind conditions, the solar tracker controller may direct the drive mechanism to pivot the table to a wind stow position to minimize wind stress on the plurality of photovoltaic modules and other components of the table of the solar tracker assembly.

Typically, a solar tracker controller is physically located in proximity to the drive mechanism of its associated solar tracker assembly. A solar tracker controller requires DC power for powering controller electronics, while the drive mechanism of the associated solar tracker assembly may include an AC drive motor or a DC drive motor. If an AC powered drive motor is used, this will require running AC power cables from a transformer on the installation site to each of the hundreds or thousands of solar tracker assemblies of the solar tracker installation site. AC power may be supplied from a utility company electrical grid or from a DC-AC inverter located on the solar tracker installation site which converts DC power generated by the photovoltaic modules of the solar tracker assemblies into AC power. If AC power is used for the powering the solar tracker controllers of the solar tracker installation, then each of the solar tracker controllers will include an AC-DC converter to convert AC power from the AC power cables to appropriate DC power for controller electronics, typically, 115 volts AC (V AC) or 230 V AC would be converted to 24 V DC for powering solar controller electronics. Alternatively, if DC power is used for powering solar tracker electronics, typically, the power comes from a single, dedicated photovoltaic module (pony panel) or from a connected string of solar tracker assembly photovoltaic modules. Depending on the configuration employed, the DC power may be at 40 V DC if, for example, a single dedicated pony panel or 1,400 V DC or more, if, for example, a connected string of 28 solar assembly photovoltaic modules is used. In either case, a DC-DC step down transformer would be used to convert the higher voltage DC power to 24 V DC for powering solar tracker electronics.

Providing AC power to each of the solar tracker assemblies for purposes of supplying power to both the solar tracker assembly drive motor and the associated solar tracker controller does have some cost savings. For example, there is no need for a battery or battery pack to store power as the AC power is available continuously from the power company electric grid. However, such savings tend to be greatly outweighed by installation costs. That is, providing AC power to each of the solar tracker assemblies in a large scale solar tracker installation is a costly undertaking for several reasons including: a) the cost of the AC power cables; and b) the installation cost associated with installing the power cables either below ground (trenching) or in above-ground cable trays on the installation site. Additionally, if AC power is supplied to the solar tracker assemblies either an AC power drive motor or a DC powered drive motor could be used. There are a number of advantages in using a DC drive motor in terms of precise positioning of table angles of inclination. Thus, if it is desired to utilize DC drive motors for the solar tracker assemblies AC-DC converters will need to be provided for each of the solar tracker assemblies. This is an additional cost associated with an AC powered solar tracker installation.

A less costly alternative to installing AC power cables to each of the solar tracker assemblies on an installation site is to use DC power to power solar tracker controller electronics and to power a DC powered drive motor. Utilizing DC power requires that DC power be supplied to each of the solar tracker controllers of the installation site and, in turn, to the DC drive motors. While DC power is available from one or more photovoltaic modules mounted to a table of a solar tracker assembly, such DC power is only available during daylight hours. Thus, during non-daylight hours, no DC power is available. This can be problematic. For example, if there is an abnormal weather condition occurring during non-daylight hours requiring the solar tracker controller to pivot the table to a wind stow position that is a different table angle of inclination from the night stow position, the solar tracker controller would need a source of DC power, other than from the one or more plurality of photovoltaic modules, in order to pivot the table appropriately. Similarly, during overcast sky conditions during daylight hours potentially no DC power is being generated by the plurality of photovoltaic modules of a solar tracker assembly, if the solar tracker controller attempts to pivot the table of the solar tracker assembly to an overcast sky angle of inclination, again, the solar tracker controller would not be able to appropriately actuate the drive mechanism and pivot the table for lack of DC power.

A rechargeable DC battery or battery pack or battery cells can be used to provide a source of DC power to operate solar tracker controller electronics and allow a motor driver of the controller electronics to actuate a DC drive motor of the solar tracker assembly and thereby pivot the table during non-daylight hours. The terms “battery” and “battery pack” and “battery cells” will be used interchangeably herein, it being understood that reference to a battery or battery pack or battery cells, as used herein, may refer to a battery configuration wherein a number of batteries or battery cells are electrically connected in a series and/or a parallel configuration to receive (charging), store and provide (discharging) DC power. Such a rechargeable battery or battery pack may work well under warm weather conditions to provide DC power to the solar tracker controller and thereby drive the DC drive motor of the drive mechanism during non-daylight hours or overcast sky conditions. However, under cold climate conditions, typically a battery's internal resistance increases, making the battery more difficult to charge and discharge. Such cold-weather battery issues have caused the owners of some solar tracker installations in cold climate regions to opt for the more expensive AC powered option for the drive mechanisms and powering the solar tracker controllers of the installation, as opposed to the less-expensive DC powered option for the drive mechanisms and solar tracker controllers. What is needed is a way to utilize DC powered solar tracker controllers under cold weather conditions that mitigates the charging/discharging problems associated with using a DC battery to power a solar tracker controller and actuate the drive mechanism under cold weather conditions.

### SUMMARY

In one aspect, the present disclosure relates to a solar tracker controller for controlling an angle of inclination of a table of an associated solar tracker assembly, the table including a plurality of photovoltaic modules and the solar tracker assembly including a drive mechanism for pivoting the table through an angle of inclination range, the solar tracker controller comprising: a) controller electronics including a motor driver controlled by the controller electronics, the motor driver electrically coupled to the drive mechanism of the associated solar tracker assembly and selectively energized by the controller electronics to actuate the drive mechanism and thereby pivot the table of the associated solar tracker assembly; b) a rechargeable battery for powering controller electronics, the rechargeable battery charged by a controller power source and having a minimum required operating temperature, the rechargeable battery including an outer surface; c) a heating element electrically controlled by the controller electronics, the heating element disposed in proximity to the outer surface of the rechargeable battery; and d) a temperature sensor electrically coupled to the controller electronics, the temperature sensor disposed in proximity to the rechargeable battery, the controller electronics monitoring an output signal of the temperature sensor indicative of the temperature of the rechargeable battery and, when the temperature of the rechargeable battery is within a predetermined range of the minimum required operating temperature, the controller electronics actuating the heating element to provide heat to the rechargeable battery to maintain the temperature of the rechargeable battery at or above the minimum required operating temperature of the rechargeable battery.

In another aspect, the present disclosure relates to a solar tracker assembly comprising: a) a table including a plurality of photovoltaic modules and a drive mechanism for pivoting the table through an angle of inclination range; and b) a solar tracker controller for controlling an angle of inclination of the table, the solar tracker controller including: 1) controller electronics including a motor driver controlled by the controller electronics, the motor driver electrically coupled to the drive mechanism of the associated solar tracker assembly and selectively energized by the controller electronics to actuate the drive mechanism and thereby pivot the table of the associated solar tracker assembly; 2) a rechargeable battery for powering controller electronics, the rechargeable battery charged by a controller power source and having a minimum required operating temperature, the rechargeable battery including an outer surface; 3) a heating element electrically controlled by the controller electronics, the heating element disposed in proximity to the outer surface of the rechargeable battery; and 4) a temperature sensor electrically coupled to the controller electronics, the temperature sensor disposed in proximity to the rechargeable battery, the controller electronics monitoring an output signal of the temperature sensor indicative of the temperature of the rechargeable battery and, when the temperature of the rechargeable battery is within a predetermined range of the minimum required operating temperature, the controller electronics actuating the heating element to provide heat to the rechargeable battery to maintain the temperature of the rechargeable battery at or above the minimum required operating temperature of the rechargeable battery.

### BRIEF DESCRIPTION OF THE DRAWINGS

The foregoing and other features and advantages of the present disclosure will become apparent to one skilled in the art to which the present disclosure relates upon consideration of the following description of the disclosure with reference to the accompanying drawings, wherein like reference numerals, unless otherwise described refer to like parts throughout the drawings and in which:

FIG. 1 is a schematic top perspective view of a solar tracker installation including a plurality of a single row, horizontal, single axis solar tracker assemblies on a solar tracker installation site, the solar installation including a set of solar tracker assemblies including adjacent, aligned rows of spaced apart solar tracker assemblies, each solar tracker assembly of the plurality of solar tracker assemblies including a drive mechanism and a pivoting table, the table including a torque tube beam including a plurality of torque tube beam segments, a plurality of photovoltaic modules; a frame for supporting the plurality of photovoltaic modules, and a plurality of bearing apparatus for rotatably supporting the torque tube beam, associated with each solar tracker assembly is a DC powered solar tracker controller that controls the drive mechanism that pivots the table through an angle of inclination range so that the plurality of photovoltaic modules track the sun as the sun moves across the sky, the solar tracker installation including a control and communications systems including an array controller in communication with each of the solar tracker controllers of the installation;

FIG. 2 is a schematic bottom perspective view of a portion of a representative single row, horizontal, single axis solar tracker assembly of the plurality of solar tracker assemblies of the solar tracker installation of FIG. 1, including the DC powered solar tracker controller associated with the solar tracker assembly operatively coupled to the drive mechanism of the solar tracker assembly, the solar tracker controller actuating the drive mechanism to change the angle of inclination of the pivoting table of the solar tracker assembly, the solar tracker assembly including a dedicated photovoltaic module for providing DC power to electronics of the solar tracker controller;

FIG. 3 is a schematic top perspective view of a portion of the solar tracker assembly of FIG. 2, for simplicity and to facilitate viewing of other components of the solar tracker assembly, only select components of the solar tracker assembly, including a single representative photovoltaic module of the plurality of photovoltaic modules of the solar tracker assembly supported by the frame is depicted in FIG. 3;

FIG. 4 is a schematic top plan view of the solar tracker assembly of FIG. 2;

FIG. 5 is a schematic vertical section view of the solar tracker assembly of FIG. 2, as seen from a plane indicated by the line 5-5 in FIG. 4;

FIG. 6 is a schematic block diagram of selected electronics and associated components of the solar tracker controller of the solar tracker assembly of FIG. 2;

FIG. 7 is a schematic block diagram of a second exemplary embodiment of a solar tracker controller of the solar tracker assembly of FIG. 2 wherein a rechargeable battery/temperature control assembly of the solar tracker controller is disposed is a second housing mounted to a support post of the solar tracker assembly and the remainder of the controller electronics are disposed in a first controller housing;

FIG. 8 is a simplified flow chart showing the decision rules utilized in maintaining battery temperature at or above one or more predetermined threshold temperatures; and

FIG. 9 is a schematic exploded front perspective view of a rechargeable battery of the DC powered solar tracker controller of the solar tracker assembly of FIG. 2, the rechargeable battery used to power the controller electronics of the solar tracker controller.

### DETAILED DESCRIPTION

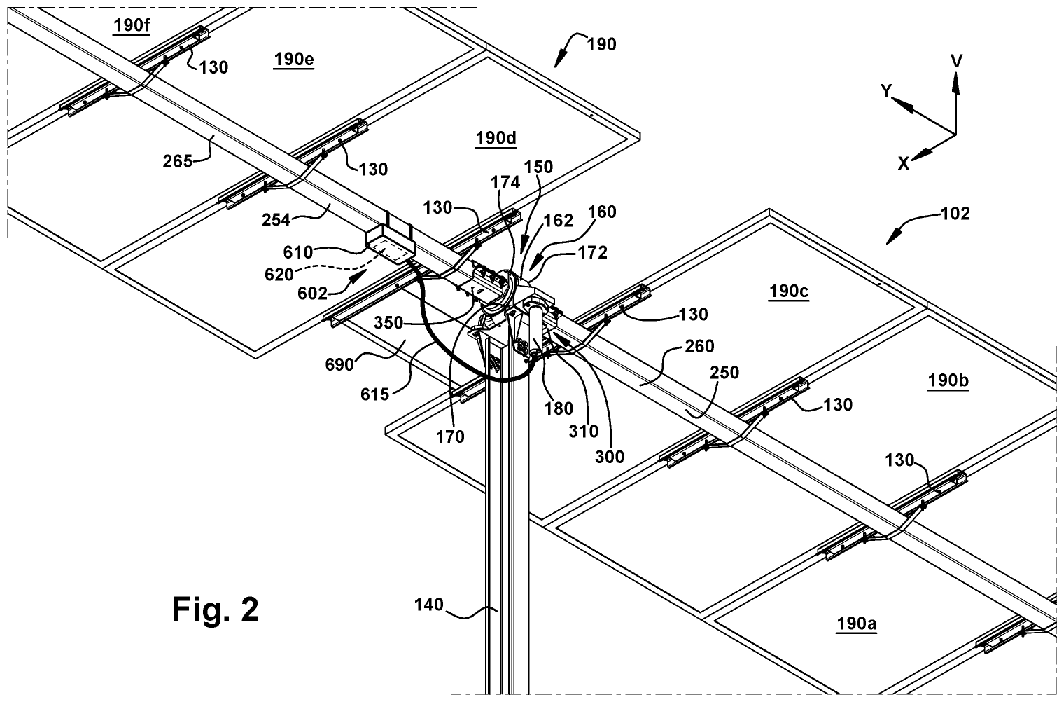

The present disclosure relates to a DC powered solar tracker controller 602 associated with single axis solar tracker assembly 102 for controlling an angle of inclination AI of a pivoting table 110 of the solar tracker assembly 102 and, more specifically, to a DC powered solar tracker controller 602 including a dedicated photovoltaic module 690 and a rechargeable battery/temperature control assembly 640 to supply DC power to controller electronics 620. Advantageously, the battery/temperature control assembly 640 facilitates operation of the solar tracker controller 602 and its electronics 620 under no/low sunlight conditions and cold climate conditions. The battery/temperature control assembly 640 operates under the control of the controller electronics 620 and includes a rechargeable battery 645 which is externally heated by a heating assembly 650. The heating assembly 650 includes a heating element 652 and a heat conductive layer or foil 655 thermally coupled to and extending from the heating element 652 and overlying an exterior or outer surface 647 of the rechargeable battery 645. When the heating element 652 is actuated, the heat conductive layer 655 conducts heat from the heating element 652 to the exterior or outer surface 647 of the battery 645 to maintain battery temperature above a desired minimum battery temperature. The heat conductive layer 655 may be, for example, a flexible sheet of heat conductive metal foil wrapped around the rechargeable battery 645. It should be appreciated, of course, that the dedicated photovoltaic module 690 may comprise a single module (as schematically depicted in FIGS. 2-4) or, alternatively, the dedicated photovoltaic module 690 may comprise an electrically coupled series of smaller dedicated photovoltaic modules. In one example embodiment, the controller electronics 620 includes a microprocessor or microcontroller 635 that utilizes battery temperature control software 637 to operate the battery/temperature control assembly 640. However, it should be appreciated that the battery temperature control software 637 may, alternatively, operate under the control of a separate processor/microprocessor/microcontroller, which communicates with the controller electronics 620.

The battery/temperature control assembly 650 additionally includes a temperature sensor 660, which monitors the temperature of the outer surface 647 of the battery 645. In one example embodiment, the temperature sensor 660 is a thermistor which engages the outer surface 647 of the battery 645. In another example embodiment the temperature sensor 660 may be attached to the outside of the heat conductive layer 655. However, in either case, the heating element 652 should be spaced as far apart from the temperature sensor 660 as possible. There are two temperature levels which need to be considered with respect to proper functioning of the rechargeable battery 645 in cold climate conditions: a) What is a minimum temperature level of the battery 645 at which charging of the battery 645 by, for example, by the dedicated photovoltaic module 690, can occur? and 2) what is a minimum temperature level of the battery 645 at which discharging of the battery 645 can occur to provide suitable DC power for operation of controller electronics 620? These two temperature levels may be different, typically, the battery 645 requires a higher temperature level for charging the battery 645 than it does for discharging the battery 645 to power controller electronics 620. Accordingly, it may be desirable to provide multiple heating parameters for heating of the battery 645 by the battery/temperature control assembly 640 that differ depending on the time of day. For example, in daytime or daylight hours, battery temperature control software 637 utilized by the microcontroller 635 may have a decision rule that maintains the battery 645 at or above a first temperature level or magnitude that is 1 degree C. above the battery's minimum required temperature for charging. This first decision rule is based on the fact that charging of the battery 645 by the dedicated photovoltaic module 690 will most likely occur during daylight hours (i.e., during the daytime or daylight hours when the dedicated photovoltaic module 690 is receiving sunlight and producing DC power).

During nighttime or non-daylight hours, the battery temperature control software 637 executed by the microcontroller 635 may have a decision rule that maintains the battery 645 at a second battery temperature level magnitude that is 1 degree C. above the battery's lower minimum required temperature for discharging. This second decision rule is based on the fact that the battery 645 is typically not charged during nighttime or non-daylight hours, as explained above, rather, it is sufficient during non-daylight or nighttime hours that the battery 645 be at a lower temperature level that allows for discharging of the battery 645 to power controller electronics 620. The heating element 652 and temperature sensor 660 are electrically coupled to the controller electronics 620 and, specifically, to the microcontroller 635, which receives output signals indicative of battery temperature from the temperature sensor 660 and, in accord with the decision rules of the battery temperature control software 637, selectively activates the heating element 653 to maintain battery temperature above first and second battery temperature levels or magnitudes, depending on whether the current time is daytime (daylight hours) or nighttime (non-daylight hours). Generally, the two decision rules may be summarized as follows: when the temperature of the rechargeable battery 645 is within a predetermined range of the minimum required operating temperature for the current time (i.e., daylight hours or non-daylight hours), the controller electronics 620 actuates the heating assembly 650 to provide heat to the rechargeable battery 645 to maintain the temperature of the rechargeable battery 645 at or above the minimum required operating temperature of the rechargeable battery 645.

As used herein, rechargeable battery 645 refers to and should be construed to cover either a single cell rechargeable battery or multiple electrically connected, rechargeable battery cells, e.g., a battery pack or multiple battery packs, electrically in series and/or in parallel. For example, a number of multiple cylindrical battery cells, for example, eight cylindrical cells, may be electrically connected and mechanically held together as a unitary structure by some material such as shrink-wrap plastic to form a desired overall shape or configuration for the rechargeable battery 645, as would be appreciated by one of skill in the art. It is the intent of the present invention that the term “battery” or “rechargeable battery” cover any rechargeable DC power source or electrically connected DC power sources that would be suitable for powering controller electronics 620.

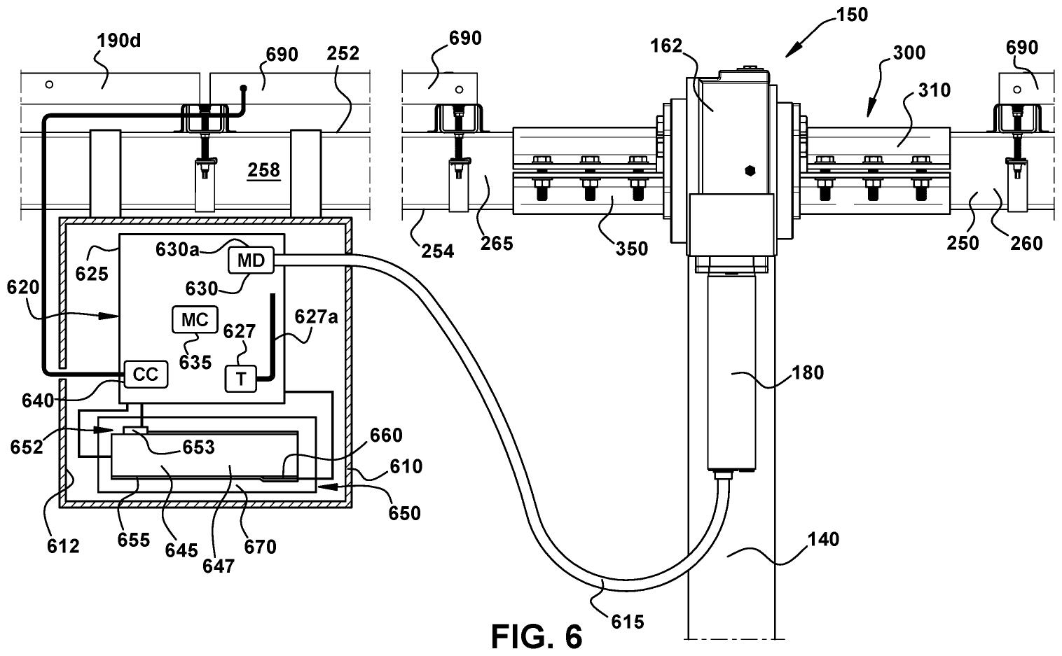

The battery/temperature control assembly 650 also includes an insulation layer 670 that overlies and surrounds the battery 645/heating element 652/temperature sensor 660 combination to ensure that the heat distributed to the battery 645 by the heat conductive layer or foil 655 is retained by the battery 645. In one exemplary embodiment, the insulation layer 670 is a sheet of closed-cell foam polymer insulation that is cut to size and affixed as an outer or overlying layer surrounding the battery 645/heating element 652/temperature sensor 660 combination. The insulating material 670 is wrapped around the battery 645 and fastened closed, by adhesive, by tape or by another method. In another exemplary embodiment, the insulation layer 670 may be affixed to an inner surface 612 of a controller housing 610 in which the controller electronics 620 and the battery/temperature control assembly 650 are disposed. In one example or exemplary embodiment, as schematically depicted in FIG. 6, the controller electronics 620, including the battery/temperature control assembly 640, are housed in a controller housing or enclosure 610 affixed or mounted to the pivoting table 110 of the associated solar tracker assembly 102. Thus, as the angle of inclination AI of the table 110 of the solar tracker assembly 102 changes, the orientation of the controller electronics 620 also changes. Certain components of the controller electronics 620 are surface mounted on a printed circuit board (pcb) 625. Included in the controller electronics 620 is an inclinometer or accelerometer 636 accelerometer to allow for determination of the angle of inclination AI of the table 110 of the solar tracker assembly 102 at any given time. For the accelerometer 636 to properly function, the accelerometer must pivot with the table 110. Since the accelerometer 636 is part of the printed circuit board 625 and is fixedly supported within the controller housing 610 and, further, since the controller housing 610 is mounted to and pivots with the torque tube beam 250 of the solar tracker assembly 102, as the table 110 pivots through a predetermined angle of inclination range AIR, the printed circuit board 625 and the accelerometer 636 mounted thereto similarly pivots in direct proportion to the angle of inclination AI of the table 110. Thus, the accelerometer 636 output signals provide an accurate measure of the current table angle of inclination AI. Accordingly, the controller housing 610 is mounted to the torque tube beam 250 of the solar tracker assembly 102.

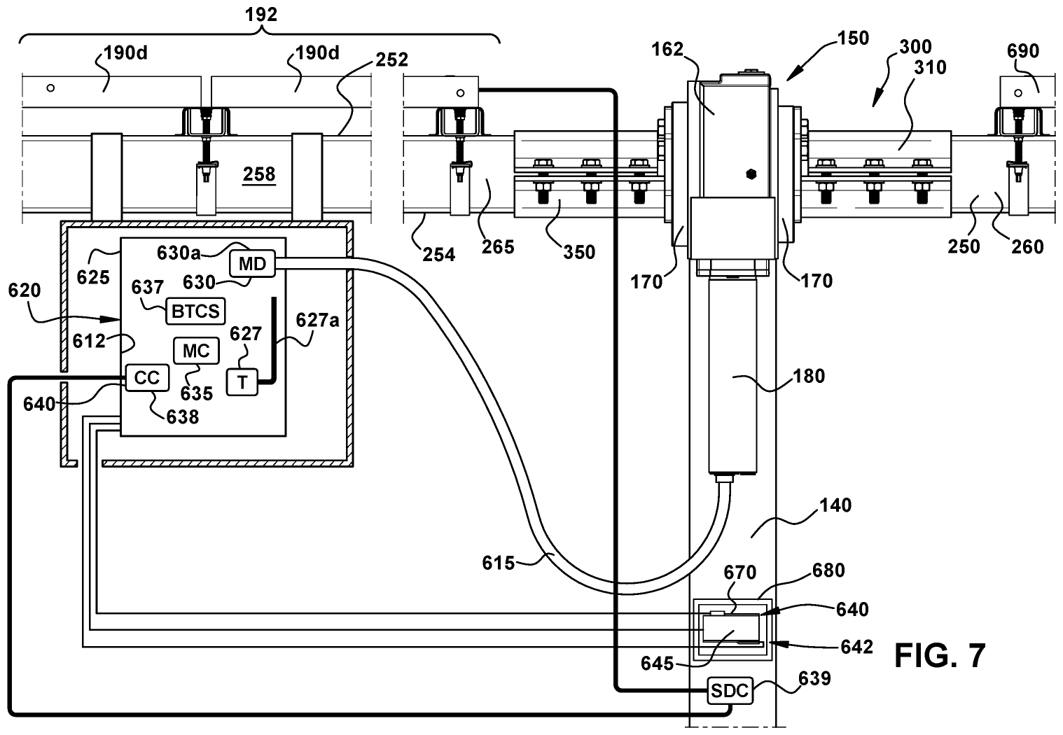

In a second example embodiment, as depicted schematically in FIG. 7, selected electronic components 642 of the battery/temperature control assembly 640 are housed in a second electronics housing or enclosure 680 mounted to a stationary support post 140 of the solar tracker assembly 102 in proximity to the controller housing 610, which houses the remaining components of the controller electronics 620. That is, the electronics 642 of the battery/temperature control assembly 640 which are not mounted to the printed circuit board PCB 624 are disposed in the second housing 690. There is no need for the electronic components 642 of the battery/temperature control assembly 640 to pivot with the table 110. Accordingly, the electronics 642 of the battery/temperature control assembly 640 may be stationary mounted to the support post 140, as opposed to being mounted to some portion of the table 110 of the solar tracker assembly 102. In one example embodiment, the controller electronics 620 mounted to the printed circuit board 625 include the microcontroller 635, the accelerometer 636, an actuator 630a for driving a DC motor 180 of a drive mechanism 150 of the solar tracker assembly 102 and a charge controller 638. The charge controller 638 manages the charging of the rechargeable battery 645 by the dedicated photovoltaic module 690 by controlling the output voltage of the dedicated photovoltaic module 690 so that the battery 645 is charged efficiently with a proper current. In one exemplary embodiment, the actuator 630a is a DC motor driver 630, which is mounted to the printed circuit board 625.

### Solar Tracker Installation 1000

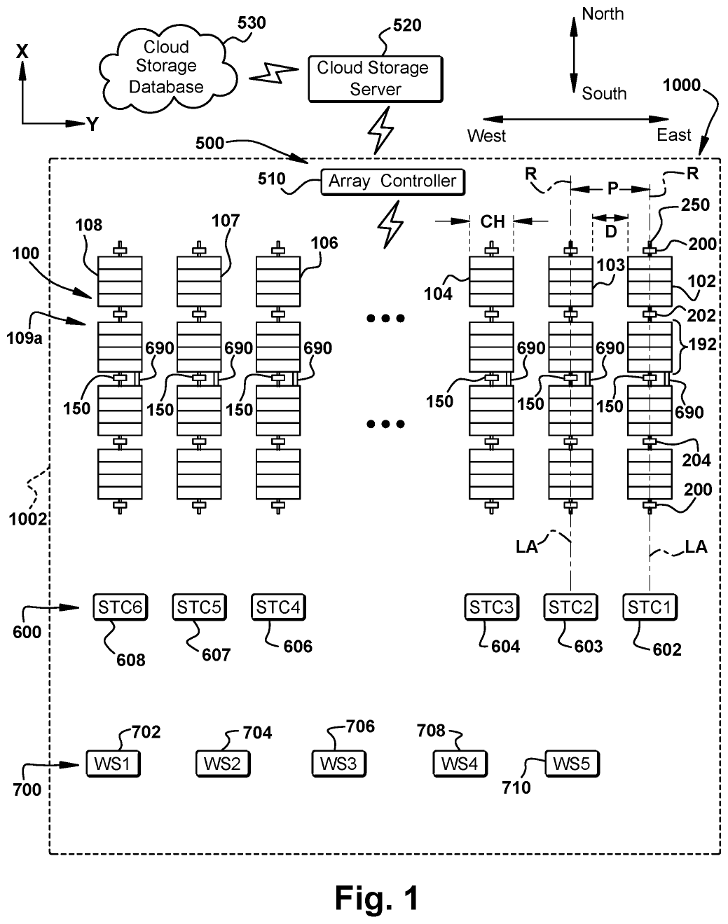

As is best seen in FIG. 1, the solar tracker assembly 102 and associated solar tracker controller 602 are representative single axis solar tracker assemblies and solar tracker controllers which are part of a solar tracker installation 1000 located on a solar tracker installation site 1002. The solar tracker installation 1000 includes a plurality of solar tracker assemblies 100. Solar tracker assemblies 102, 103, 104, 106, 107, 108 are schematically depicted in FIG. 1, along with their associated solar tracker controllers 602, 603, 604, 606, 607, 608. In one exemplary or example embodiment, each of the plurality of solar tracker assemblies 100 is a horizontal, single axis solar tracker assembly and each solar tracker assembly of the plurality of solar tracker assemblies 100 operates under the control of an associated different one of a plurality of solar tracker controllers 600 for example, representative solar tracker controllers 602, 603, 604, 606, 607, 608 are schematically depicted in FIG. 1. In one exemplary or example embodiment, each of the plurality of solar tracker controllers 600 is located in proximity to or mounted on its associated solar tracker assembly, for example, solar tracker controller 602 is mounted on a rotatable torque tube beam 250 of its associated solar tracker assembly 102. The plurality of solar tracker controllers 600 are part of a solar tracker control and communications system 500, which includes an array controller 510 which is in wireless communication with each of the plurality of solar tracker controllers 600 and in wireless communication with each of a plurality of weather sensors 700 on the installation site 1002.

The control and communications system 500 advantageously employs a long-range, radio frequency, sub GHz, wireless data communications protocol and a star wireless communications network configuration to allow for centralized control of the installation 1000 by the array controller 510 and provide for efficient, wireless transmission of data and control signals between the array controller 510, each of the plurality of solar tracker controllers 600, and each of the plurality of weather sensors 700. The array controller 510 is also in wireless communication with a cloud storage database 530 via a cloud storage server 520. Additional details of the solar tracker control and communications system 500 suitable for a large-scale solar tracker installation are disclosed in U.S. Pub. No. US 2023/0378901 A1 to Kesler et al., published Nov. 23, 2023, and entitled Large-Scale Solar Tracker Installation Control System. U.S. Pub. No. US 2023/037890 A1 is assigned to the assignee of the present application and is incorporated by reference herein in its entirety.

### Solar Tracker Assembly 102

It should be understood that the description of the representative solar tracker assembly 102 and its associated DC powered solar tracker controller 602 similarly applies to the configuration and function of the remaining solar tracker assemblies of the plurality of solar tracker assemblies 100 and the remaining solar tracker controllers of the plurality of solar tracker controllers 600. The solar tracker controller 602 controls the in-line drive mechanism 150 of the solar tracker assembly 102 to rotate the table 110 of the solar tracker assembly 100 about a table axis of rotation R. The table 110 of the solar tracker assembly 102 includes a frame 120 supporting a plurality of photovoltaic modules 190 as well as the smaller, dedicated photovoltaic module 690 that charges the rechargeable battery 645 and is part of the solar tracker controller 602 and the battery/temperature control assembly 650. The rotatable torque tube beam 250 of the table 110, in turn, supports the frame 120. A plurality of bearing apparatuses 200, in turn, rotatably support the torque tube beam 250. The torque tube beam 250 is comprised of a plurality of aligned and couple torque tube beam segments. In the drawings, four torque tube beam segments, namely, first, second, third and fourth torque tube beam segments 260, 265, 270, 275 of the torque tube beam 250 are schematically depicted, it being understood that the solar tracker assembly 100 includes additional torque tube beam segments not shown. The plurality of bearing apparatuses 200 are advantageously configured and positioned such that, other than the first and second torque tube beam segments 260, 265 of the torque tube beam 250 adjacent the in-line drive mechanism 150, the table axis of rotation R, is vertically aligned with, that is, would pass through or be acceptably close, for design purposes, to passing through a center of gravity or center of mass of the table 110. As used herein, the direction X is a horizontal direction parallel to the torque tube beam longitudinal axis LA, typically, in the north-south direction, the direction Y is a horizontal direction orthogonal to the torque tube beam longitudinal axis LA, typically in the east-west direction, and the direction V is a vertical direction orthogonal to X and Y directions. The vertical direction V includes the upward direction UP, away from the ground/substrate G, and the downward direction DW, toward the ground/substrate. For simplicity, it is assumed that the ground/substrate is horizontal (orthogonal to the vertical direction V) extending along and in the region of the torque tube beam 250.

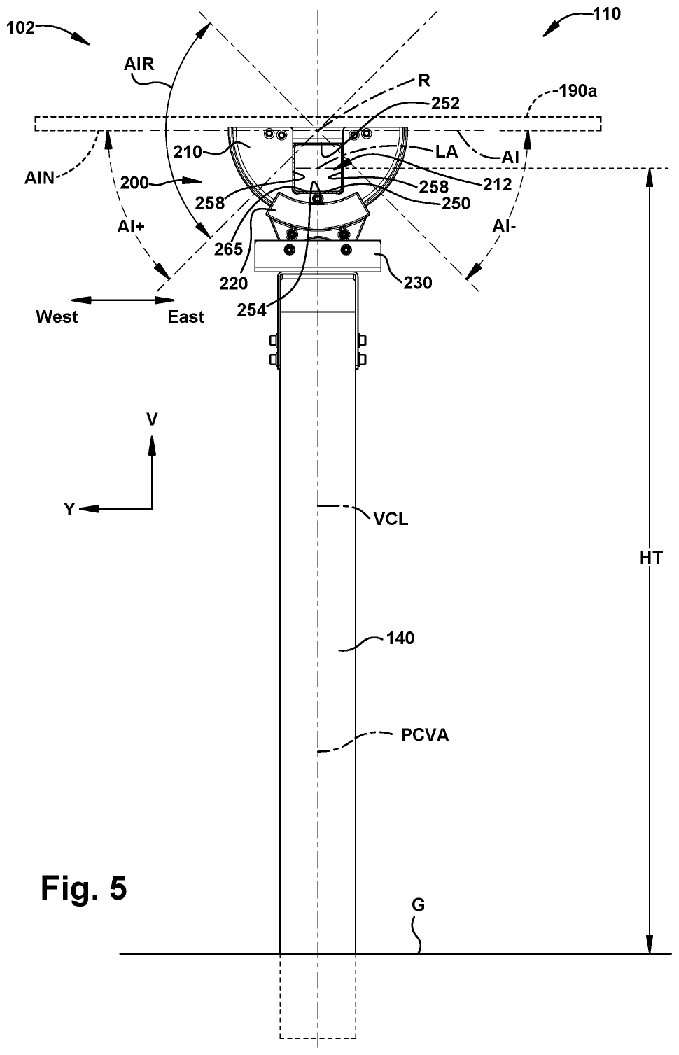

The solar tracker assembly 102 of the present disclosure includes the drive mechanism 150 which, operating under the control of the solar tracker controller 602, pivots or rotates the table 110, including the plurality of photovoltaic modules 190, about the axis of rotation R. The table 110 pivots through an angle of inclination A1 such that the plurality of photovoltaic modules 190 follow a position of the sun as the sun moves from east to west. As best seen in FIG. 5, the table 110 rotates through the predetermined angular inclination range AIR between a maximum negative angle of inclination A1—wherein the plurality of photovoltaic modules 190 are facing in an easterly direction to receive sunlight at sunrise and a maximum positive angle of inclination AI+ wherein the plurality of photovoltaic modules 190 are facing in a westerly direction to receive sunlight at sunset. At a neutral angle of inclination AlN, the plurality of photovoltaic modules 190 are substantially horizontal, that is, with their upper light receiving surfaces facing directly upward, as would be the case at high noon where the sun is at its apex in the sky.

In one exemplary embodiment, the single axis solar tracker assembly 102 is a single row, horizontal, single axis solar tracker assembly and the drive mechanism 150, controlled by the solar tracker controller 602, comprises a single slew drive or slew gear drive 160 which pivots the table 110 through the predetermined angle of inclination range AIR to track movement of the sun across the sky/horizon. However, one of skill in the art would appreciate that the concepts of the present disclosure are equally applicable to multiple row solar tracker systems, that is, multiple, spaced apart, parallel rows of solar tracking assemblies, as well as solar tracker systems where multiple slew drives are utilized within a single row to pivot the table 110. The table 110 includes all rotating or pivoting components of the solar tracker assembly 100 including: a) the plurality of photovoltaic modules 190, b) the frame 120 including the plurality of mounting brackets 130 which support the plurality of photovoltaic modules 190 and couple the plurality of photovoltaic modules 190 to the torque tube beam 250, c) the torque tube beam 250, extending generally in a north-south direction and extending horizontally, that is, parallel to the ground G, supports the frame 120 and, in turn, is driven through the angle of inclination range AIR by a rotating drive or rotatable drive member 170 of the drive mechanism 150; d) the rotatable bearing assemblies 210 of each of the plurality of bearing apparatuses 200 positioned at spaced apart intervals along the torque tube beam 250 which rotatably support the torque tube beam 120 (and thereby the frame 120 and plurality of photovoltaic modules 190) and define the axis of rotation R of the table 110; e) the rotating drive 170 of the slew drive 160; f) the controller housing 610 and controller electronics 620 supported within the housing 610; and g) the dedicated photovoltaic module 690.

Each bearing apparatus, for example first and second bearing apparatuses 202, 204 of the plurality of bearing apparatuses 200 includes the rotatable or rotating bearing assembly 210, the stationary saddle assembly 220 and a connecting assembly 230. The torque tube beam 250 extends through and is supported by the rotatable bearing assembly 210 which rotates the torque tube beam 250 about the table axis of rotation R. The rotatable bearing assembly 210 of the bearing apparatus 200, in turn, is supported by the stationary saddle assembly 220. The stationary saddle assembly 220 constrains the pivoting or rotation of the rotatable bearing assembly 210 such that the bearing assembly and the torque tube section extending through and supported by the rotatable bearing assembly 210 rotate about a bearing axis of rotation. The table axis of rotation R (except in the region of the slew drive 160) is collectively defined by axes of rotation of the plurality of bearing apparatuses 200 positioned at spaced apart internals along the extent of the torque tube beam 250. Stated another way, each bearing axis of rotation of each bearing apparatus defines a portion of the overall table axis of rotation R. The individual axis of rotation of each of the plurality of solar tracker bearing apparatuses 200 are substantially aligned to or coincident to form a single or combined table axis of rotation R. The exception to this is the region or segments of the torque tube beam 250 adjacent the slew drive 160 and the first and second concentric drive journals 310, 350. In this region, the axis of rotation R of the table 110 is defined by the drive mechanism axis of rotation that is, the axis of rotation of the rotating drive or rotating drive member 170 of the slew drive 160.

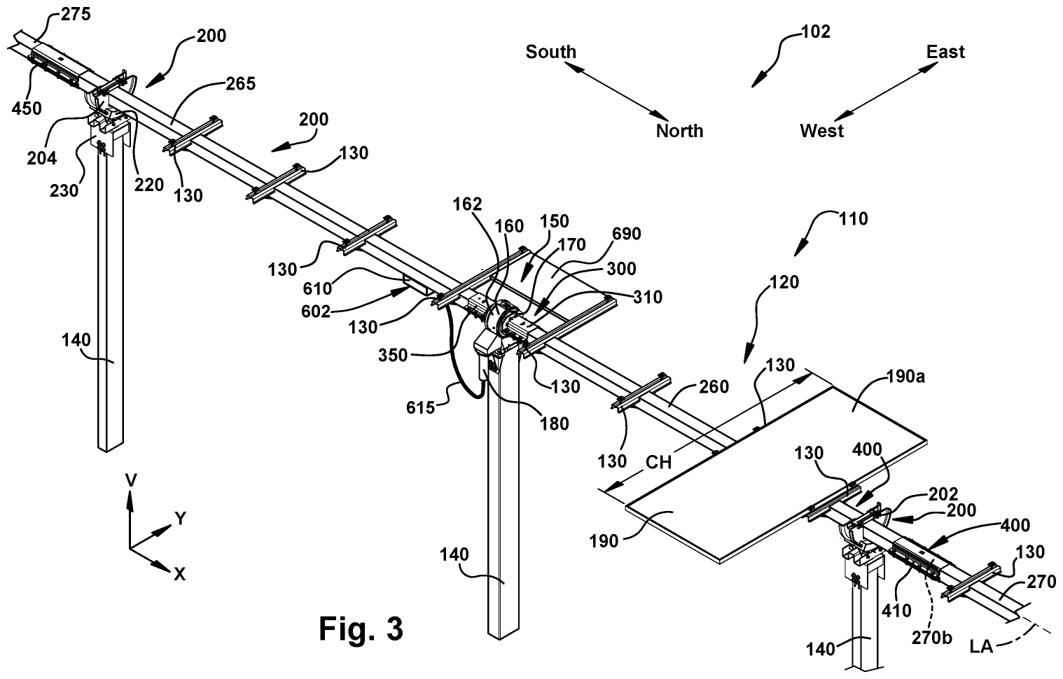

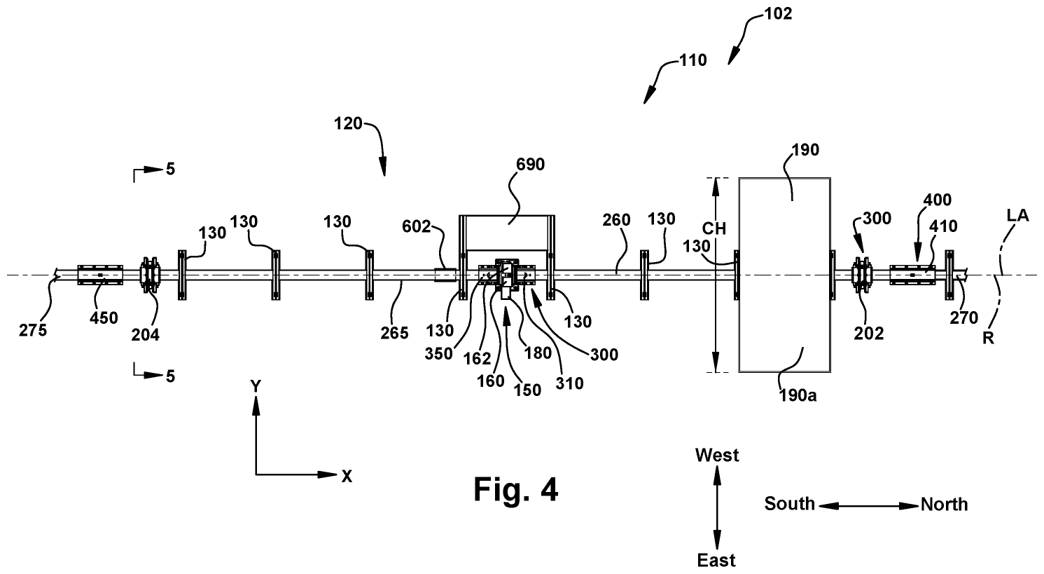

As can best be seen in FIG. 5, the stationary saddle assembly 220 is mounted by the connecting assembly 230 to a support post 140, which is driven into the ground/substrate G or otherwise secured in the ground/substrate G by, for example, concrete. Thus, the support post 140 and connecting assembly 230 determine the position and the vertical height HT of the rotatable bearing assembly 200. Each of the support posts 140 extend in the vertical direction V along a vertical center line or central vertical axis PCVA (FIG. 5) of the support post 140. For each of the support posts 140, a vertical center line VCL of the bearing assembly 200 is aligned with the center line of the support post 140. The slew drive 160 is similar affixed to a support post 140, which determines the position and vertical height of the rotating drive 170 of the slew drive 160 for purposes of a concentric drive configuration. The frame 120, in one exemplary embodiment, includes a plurality of mounting brackets 130 which are spaced along the longitudinal extent of the torque tube beam 250 and each of which is affixed to the torque tube beam 250. Each of the plurality of mounting brackets 130 function to individually secure each photovoltaic module, such as the representative photovoltaic module 190a, of the plurality of photovoltaic modules 190 to the torque tube beam 250. For simplicity, only the single representative photovoltaic module 190a is schematically depicted in FIGS. 3 and 4. Also not shown in the drawings are a number of clamps and fasteners, which are part of the frame 120 and facilitate securing the plurality of photovoltaic modules 190 to the plurality of mounting brackets 130 and securing the plurality of mounting brackets 130 to the torque tube beam 250. Additional details concerning the configuration of the bearing apparatuses and the frame/mounting brackets may be found in U.S. Pat. No. 10,944,354 to Ballentine et al. and U.S. Pat. No. 11,271,518 to Ballentine et al., both of which are assigned to the assignee of the present application and both of which are incorporated herein by reference in their respective entireties.

In one exemplary embodiment, the torque tube beam 250 comprises a hollow metal tube that is substantially square in cross section, having an open interior that is centered about a central longitudinal axis LA. In one exemplary embodiment, the torque tube beam 250 is approximately 100 mm. by 100 mm. (approximately 4 in. by 4 in.) and includes an upper wall 252 and a lower wall 254 spaced apart by parallel side walls 258. The torque tube beam 250 extends along the longitudinal axis LA of the torque tube beam 250 and, as noted above, extends generally parallel to the ground G. Hence, as the ground is generally horizontal, the solar tracker assembly is referred to as a horizontal, single axis solar tracker assembly 100. The torque tube beam 250 is comprised of a number of connected torque tube beam segments, each of which is approximately 40 feet in length. In the schematic depiction of FIGS. 1, 2, 4 and 5, only a portion of the solar tracker assembly 100 and, thus, only a portion of the extent of the torque tube beam 250 and the frame 120 and a portion of the total number of bearing apparatuses of the plurality of bearing apparatuses 200 are shown. For example, in FIGS. 3 and 4, the first and second torque tube beam segments 260, 265 and portions of the third and fourth torque tube beam segments 270, 275 are schematically depicted. Of course, it should be appreciated that given that a torque tube beam segment is typically 40 feet in length and a typical photovoltaic module, such as the representative photovoltaic module 190a is approximately 1 meter by 2 meters and is mounted to the torque tube beam 250 in portrait orientation, many more photovoltaic modules would be present on any given torque tube beam segment than is schematically depicted in the FIGS. 1-4. Given that the plurality of photovoltaic modules 190 are supported in portrait orientation by the plurality of mounting brackets 130, a width or chord CH of the table 110 is typically 2 meters.

Depending on the table configuration, the plurality of photovoltaic modules 190 may be in landscape or portrait orientation with respect to the torque tube beam 250. For example, in a so-called “one-in-portrait” photovoltaic module mounting configuration for the solar tracker assembly 102, a single row of photovoltaic modules overlies the torque tube beam 250 and extend outwardly in an east-west direction from the torque tube beam 250. If each of the photovoltaic modules of the plurality of photovoltaic modules 190 of the solar tracker assembly 102 includes a 2 meter long by one meter wide photovoltaic module which is mounted to the torque tube beam 250 by the frame 120, then approximately one meter of each photovoltaic module will extend outwardly on either side of a center of the torque tube beam 250, as the solar tracker assembly 102 is viewed in top plan view. To achieve a proper balance, the photovoltaic modules of the solar tracker assembly are positioned such that that a total weight of the frame 120, including the plurality of photovoltaic modules 190 and associated mounting components of the frame 120 (e.g., module rails, clamps, brackets and fasteners), are approximately equally distributed on either side of the torque tube beam 250, as viewed in top plan view. As viewed in top plan view, an extent of each photovoltaic module, as measured in an east-west direction, when the module 190a is horizontal, is referred to as the chord or chord value, while a distance between adjacent solar tracker assemblies, for example, adjacent solar tracker assemblies 102, 103, as measured between center lines of the torque tube beam 250, is referred to as a pitch or pitch distance P (FIG. 1). The ratio of chord to pitch is typically about 3:1 for a so-called “one-in-portrait” photovoltaic module mounting configuration. For example, if the photovoltaic modules each have a dimension of 2 meters by 1 meter, in a “one-in-portrait” photovoltaic module mounting configuration, each module is mounted to the torque tube beam 250 such that the 2 meter length of the photovoltaic module extends in the east-west direction and the 1 meter length extends along the torque tube beam in the north-south direction. In such a “one-in-portrait” configuration, the chord value CH is 2 meters, while the pitch distance P will be on the order of 6 meters. Accordingly, a distance D (FIG. 1) between facing edges of the photovoltaic modules 190 of solar tracker assemblies 102, 103 would be approximately 4 meters. Of course, it should be appreciated that given that a torque tube beam segment is typically 40 feet in length many more photovoltaic modules would be present on any given torque tube beam segment than is schematically depicted in FIGS. 1-4.

The solar tracker assembly 100, in one exemplary embodiment may include five, 40-foot torque tube beam segments on one side of the drive mechanism 150 and another five, 40-foot torque tube beam segments on an opposite side of the drive mechanism 150 providing a total north-south extent or length of the torque tube beam 250 of approximately 400 feet. End portions of adjacent torque tube beam segments, such as, for example, first and third torque tube beam segments 260, 270, are affixed together by a first coupler 410 (FIGS. 3 and 4) of a plurality of couplers or splicing members 400 and the second and fourth torque tube beam segments 265, 275 are affixed together by a second coupler 450 of the plurality of couplers 400. A first end portion of the first torque tube beam segment 260, is received by and affixed to the first concentric drive journal 310. Similarly, a first end portion of the second torque tube beam segment 265 is received by and affixed to the second concentric drive journal 350.

The representative solar tracker assembly 102 includes the drive mechanism 150 which, in one exemplary embodiment, includes the slew drive 160 having the stationary housing 162 supporting the rotating drive member 170. The drive mechanism 150 of the solar tracker assembly 102 operates under the control of the solar tracker controller 602 to pivot or rotate the table 110, including the plurality of photovoltaic modules 190, about the table axis of rotation R. Disposed within the stationary housing 162 is a gear train of the slew drive 160 which is operatively coupled to and drives the rotating drive member 170 about a drive mechanism axis of rotation. The drive mechanism 150 further includes the DC motor 180 coupled to the stationary housing 162 of the slew drive 160. In one exemplary embodiment, the DC motor 180 is a brushed 24 V DC motor. An output shaft of the DC motor 180 is operatively connected to a gear train of the slew drive 160 such that rotation of the output shaft of the DC motor 180 rotates the slew drive gear train. The slew drive gear train, in turn, is operatively coupled to the rotating drive member 170 of the slew drive 160 such that actuation of the DC motor 180 and rotation of the DC motor output shaft causes a proportional and precise rotation of the rotating drive member 170 of the slew drive 160. This rotation of the slew drive rotating drive member 170, in turn, precisely rotates the table 110 of the solar tracker assembly 102 to a desired table angle of inclination AI. That is, rotation of the rotating drive member 170 of the slew drive 160 by the DC motor 180 causes a precise rotation of the table 110 of the solar tracker assembly 102 to a desired table angle of inclination AI (within, of course, the limits of the table angle of inclination range AIR). Additional details regarding the structure and function of a horizontal, single axis solar tracker assembly are disclosed in U.S. Pat. No. 10,944,354 to Ballentine et al., issued Mar. 9, 2021 (“the '354 patent”), and U.S. Pat. No. 11,271,518 to Ballentine et al., issued Mar. 8, 2022 (“the '518 patent”), both of which are assigned to the assignee of the present application. Both the '354 patent and the '518 patent are incorporated by reference herein in their respective entireties.

Solar Tracker Controller 602 with Heated Rechargeable Battery 645

As discussed above, the tracker controller 602 controls, among other things, the angle of inclination AI of the table 100 of its associated solar tracker controller 102. The solar tracker controller 702 includes the controller electronics 620. The controller electronics 620 includes both the electronics disposed within the controller housing 610 and, if the second electronic housing 680 (FIG. 7) is utilized for enclosing selected electronic components 642 of the battery/temperature control assembly 640, those electronics as well. The controller electronics 620 also includes the actuator 630a for actuating the drive mechanism 150 of the solar tracker assembly 102 to pivot, as required, the angle of inclination AI of the table 100 of the solar tracker assembly 102 such that the upper surfaces of the plurality of photovoltaic modules 190 and an upper surface of the dedicated photovoltaic module 647 track the sun as it moves across the sky. In one exemplary embodiment, the actuator 630a comprises the DC motor driver 630 which is coupled to the DC drive motor 180 of the drive mechanism 150 of the solar tracker assembly 102. The DC motor driver 630 of the solar tracker controller 602 precisely actuates or drives the DC drive motor 180 of the drive mechanism 150 to precisely rotate or pivot the table angle of inclination AI of the solar tracker assembly 102. The solar tracker controller 602 also includes the dedicated photovoltaic module 690 that charges, via the charge controller 638, the rechargeable battery 645. The controller electronics 620 includes the microprocessor or microcontroller 635 which is surface-mounted on the printed circuit board 625 disposed in the controller housing 610. The controller electronics 620 also includes a LoRa wireless communications device or transceiver 627 and an associated antenna 627a fabricated on the printed circuit board 625. The transceiver 627, in one example embodiment, may be integrated into the microcontroller 635. As noted above, the print circuit board 625 also includes other components of the controller electronics 620 including the accelerometer 636 and the charge controller 638.

The battery/temperature control assembly 640 includes the DC rechargeable battery 645 which stores power generated by the dedicated photovoltaic module 647, the heating assembly 650 and the temperature sensor 660. The heating assembly 650 and the temperature sensor 660 operate under the control of the microcontroller 635 to monitor a temperature of the outer surface 647 of the battery 645 and, as required, under the control of the microcontroller 635, actuates the heating assembly 650 to maintain a temperature of the battery 645 above one or more threshold temperatures. The microcontroller 635 utilizes the battery temperature control software 637 which provides decision rules for maintaining battery temperature. During daytime or daylight hours, the battery temperature is maintained above the first temperature value or level such that the battery can be successfully charged by the dedicated photovoltaic module 690. The first temperature value may be, for example, a battery temperature level that is 1 degree C. above the battery's minimum required temperature for charging based on the fact that charging of the battery 645 by the dedicated photovoltaic module 690 must occur during daylight hours.

During nighttime or non-daylight hours, the battery temperature is maintained above the second temperature value or level such that the battery can be successfully discharged to power the controller electronics 620. The second temperature value may be, for example, a battery temperature level 1 degree C. above the battery's minimum required temperature for discharging based on the fact that the battery 645 is not charged during nighttime hours. However, during nighttime or non-daylight hours the battery 645 will be required to discharge to power controller electronics 620 and, as required, pivot the table 110 of the solar tracker assembly 102 if a high wind condition is sensed by the plurality of weather sensors 700 and, the solar tracker controller 602 seeks to actuate the motor driver 630 to pivot the table 100 from a first angle of inclination corresponding to a night position to a second angle of inclination corresponding to a high wind condition. Advantageously, heating the battery 645 with the heating assembly 650 and monitoring the temperature of the battery 645 with the temperature sensor 660, per the present disclosure, mitigates charging/charge capacity/discharge problems associated with using a DC battery to power the electronics of a DC powered solar tracker controller. The battery/temperature control assembly 640 of the present disclosure provides for use of a DC powered solar tracker controller 602 for actuating the drive mechanism 150 of the solar tracker assembly 102 that change the table angle of inclination AI under cold weather conditions and during overcast conditions.

In one example embodiment, a power source used to charge the rechargeable battery 645 of the battery/temperature control assembly 640 is the dedicated photovoltaic module 690. As can be seen in the schematic depictions of the dedicated photovoltaic module 690 in FIGS. 1-4, the dedicated photovoltaic module 690 is typically physically smaller than the photovoltaic modules 190a, 190b, 190c, 190d, 190e, 190f of the plurality of photovoltaic modules and generates less DC power under full sunlight conditions that does a photovoltaic module of the plurality of photovoltaic modules 190. In one exemplary embodiment, each photovoltaic module of the plurality of photovoltaic modules generates a power output of approximately 500 watts during full sunlight conditions, while the dedicated photovoltaic module 690 generates a power output of approximately 30-60 watts which is input to the charge controller 638 which adjusts the voltage to an appropriate voltage, e.g., 24 volts DC to charge the battery 645.

In an alternate example embodiment, string power may be utilized as an alternative power source to charge the rechargeable battery 645. String power refers to the use of a series or subset of electrically connected (string) of photovoltaic modules 192 of the plurality of photovoltaic modules 190 to supply DC power to charge the rechargeable battery 645 of the battery/temperature control assembly 640 of the solar tracker controller 602. Specifically, in one example embodiment of the string power configuration, a string of electrically coupled, adjacent photovoltaic modules 192 disposed between the drive mechanism 150 and the bearing assembly 202 may be used to charge the rechargeable battery 645, instead of using the dedicated photovoltaic module 690. While the schematic depiction of the solar tracker assembly 102 in FIG. 1 show four adjacent photovoltaic modules in the photovoltaic module string 192, it should be appreciated that an actual string would include a much larger number of photovoltaic modules in the photovoltaic module string 192, typically, on the order of 30 photovoltaic modules in one series-connected string of photovoltaic modules. In the 30 photovoltaic module string power exemplary embodiment, the power output of the string 192 would be approximately 15,000 watts (500 watts/module×30 photovoltaic modules/string), with a DC voltage of approximately 1,500 volts. Assuming that the rechargeable battery 645 requires 24 volts DC, the charge controller 638 of the controller electronics must be placed in series with a DC-DC step-down voltage converter 639 (FIG. 7) to step down the string voltage from 1500 volts DC to approximately 24 volts DC which is then input to the charge converter 638. The step-down voltage converter 639 may be disposed in the electronics housing 610 mounted to the torque tube beam 250 or disposed in the second housing 680 mounted to the support post 140, or the step-down voltage converter 639 may be housed in a separate enclosure, as is schematically depicted in FIG. 7. In comparing the two power sources for charging the rechargeable battery 645, the string of photovoltaic modules 192 (hereinafter string power 192) vs. the dedicated photovoltaic module 690, the string power 192 has the advantage of being better able to provide power to recharge the battery 645 under overcast conditions because the physical footprint or light receiving area of the string of photovoltaic modules 192 is much greater than the corresponding light receiving area of the dedicated photovoltaic module 690. Additionally, the cost of the dedicated photovoltaic module 690 is avoid as no such module is required. The disadvantage of string power 192 is the additional cost associated with purchasing and installing and wiring the DC-DC step down voltage converter 639.

In one exemplary embodiment, the rechargeable battery 645 is a lithium iron phosphate (LiFePO₄) battery is used. If a LiFePO₄ battery is used, the decision rules of the battery/temperature control software 637 may be summarized as follows. A very simple decision rule combines the two decision rules into a single rule, i.e., during both daytime (daylight hours) and nighttime (non-daylight hours) keep the battery above 0 degrees C. A better and more complex decision rules are as follows: First decision rule for daytime (daylight hours)—maintain the battery temperature above 0 C during daylight hours. Second decision rule for nighttime (non-daylight hours)—maintain the battery temperature above −10 C during non-daylight hours, so long as the battery's state of charge is not below a predetermined threshold level of charge. These objectives can be achieved by looking at the battery's temperature at some interval, such as every 10 minutes. During daylight hours, when the battery temperature is within 1 degree C. of the first temperature value, turn on the heating element 652 and monitor the battery temperature more frequently, until the temperature rises to 3 degrees C. above the first temperature value and then turn the heating element 652 off. When the heating element 652 is turned on, the metallic foil 655 will distribute the heat evenly around the outer surface 647 of the battery 645, and the insulation layer 670 will keep most of the heat in the battery 645. The battery/temperature control software 637 will enable the adjustment of the first and second decision rules as needed and will record battery temperature data and the use of battery power to heat or warm the battery 645. Thus, over time the operation of the battery/temperature control assembly 640 may be evaluated and improved.

The LiFePO₄ battery 645 performs well down to 0 degrees C. The LiFePO₄ battery 645 will still discharge below 0 degrees C. to allow the tracker controller electronics 620 to operate and actuate the drive mechanism 150 to pivot the angle of inclination AI of the table 110 of the solar tracker assembly 102. However, the LiFePO₄ battery 645 will not charge below 0 degrees C., so the battery 645 will become depleted, even if the sun shines bright on the dedicated photovoltaic module 690. Below −10 degrees C., the LiFePO₄ battery 645 will not charge or discharge, thus, after depletion of the battery 645, the solar tracker controller 602 will no longer function to change the angle of inclination AI of the solar tracker assembly table 110. There are two ways in which the solar tracker controller's operation can be thwarted by low temperature: a) during daylight hours, if the temperature is too low to charge the battery 645, the battery will eventually be depleted and the solar tracker controller 602 will cease operation; and 2) during nighttime or non-daylight hours, if the temperature is too low to allow the battery 645 to discharge, the solar tracker controller 602 will cease operation. The battery/temperature control assembly 640 of the present disclosure, in concert with the two decision rules of the battery temperature control software 637 as executed by the microcontroller 635, mitigate the low temperature issues by heating the rechargeable battery 645. Additionally, since the battery 645, when charged, has power reserves, the battery 645 can continue to provide power to the controller electronics 620 to allow for operation of the controller 602 under overcast sky and nighttime conditions, at least for a limited period of time.

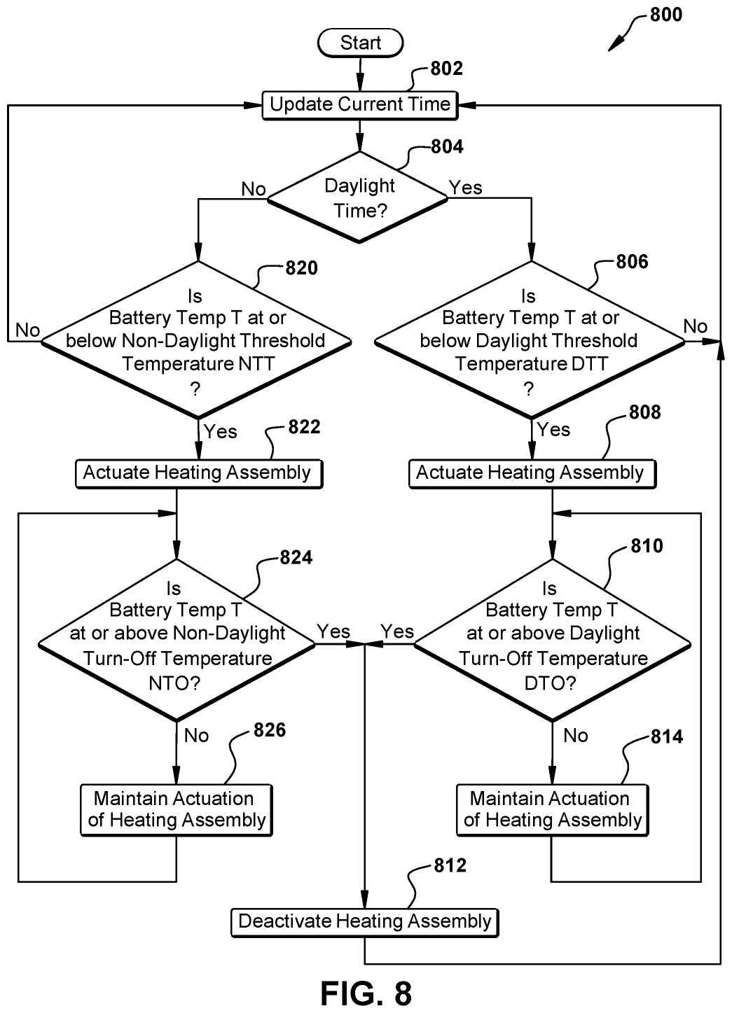

A simplified flow chart is shown in FIG. 8 that illustrate a method or process of controlling battery temperature T executed by the microcontroller 635 utilizing the battery temperature control software 637 and operating the battery/temperature control assembly 640. The method is shown generally at 800 in FIG. 8 uses two decision rules—one decision rule for daylight hours or time periods and a second decision rule for non-daylight hours or time periods. The method is shown generally at 800 in FIG. 8. At step 802, the current time is updated. At step 804, a determination is made if the current time is a daylight time or a non-daylight time. If the current time is a daylight time, the first decision rule is applied as follows. At step 806, a determination is made if the battery temperature T (as measured by the temperature sensor 660) is at or below a predetermined daylight threshold temperature DTT. If the battery temperature T is above the predetermined daylight threshold temperature DTT, then the process 800 returns to step 802 and the current time is updated, that is, the battery 645 is at a sufficiently high temperature T that it is capable of being charged by the dedicated photovoltaic module 690 and is capable of discharging, as required, operate the controller electronics 620. If, on the other hand, at step 806, the battery temperature T is at or below the daylight threshold temperature DTT, then, at step 808, the heating assembly 650 is actuated to heat the outer surface 647 of the battery 645. At step 810, the determination is made as to if the battery temperature T is at or above a daylight turn-off temperature DTO. If, the answer to the determination at step 810 is yes, then the outer surface 647 of the battery 645 is at an acceptably high level or magnitude of battery temperature T such that, at step 812, the heating assembly 650 is deactivated and the process 800 returns to step 802 where the current time is updated. If at step 810, the answer is no, then at step 814, the heating assembly 650 remains activated to continue heating the battery 645 and the process loops back to step 810 until such time at the battery temperature T exceeds the daylight turn-off temperature DTO. Essentially, the process 800 maintains the heating assembly 650 in an energized state to heat the battery 645 when the battery temperature T is in a predetermined range between the daylight threshold temperature DTT and the daylight turn-off temperature DTO or if the battery temperature T is below the daylight threshold temperature DTT. This range will be referred to herein as a predetermined range of the minimum required operating temperature for daylight time periods.

If at step 804, the current time is a non-daylight time, the second decision rule is applied as follows. At step 820, a determination is made if the battery temperature T (as measured by the temperature sensor 660) is at or below a predetermined non-daylight threshold temperature NTT. If the battery temperature T is above the predetermined non-daylight threshold temperature NTT, then the process 800 returns to step 802 and the current time is updated, that is, the battery 645 is at a sufficiently high temperature T that it is capable of discharging, as required to operate the controller electronics 620. If, on the other hand, at step 820, the battery temperature T is at or below the non-daylight threshold temperature NTT, then, at step 822, the heating assembly 650 is actuated to heat the outer surface 647 of the battery 645. At step 824, the determination is made as to if the battery temperature T is at or above a non-daylight turn-off temperature NTO. If, the answer to the determination at step 824 is yes, then the outer surface 647 of the battery 645 is at an acceptably high level or magnitude of battery temperature T such that, at step 812, the heating assembly 650 is deactivated and the process 800 returns to step 802 where the current time is updated. If at step 824, the answer is no, then at step 826, the heating assembly 650 remains activated to continue heating the battery 645 and the process loops back to step 824 until such time at the battery temperature T exceeds the non-daylight turn-off temperature NTO. Essentially, the process 800 maintains the heating assembly 650 in an energized state to heat the battery 645 when the battery temperature T is in a predetermined range between the non-daylight threshold temperature NTT (or below) and the non-daylight turn-off temperature NTO. This range will be referred to herein as a predetermined range of the minimum required operating temperature for non-daylight time periods.

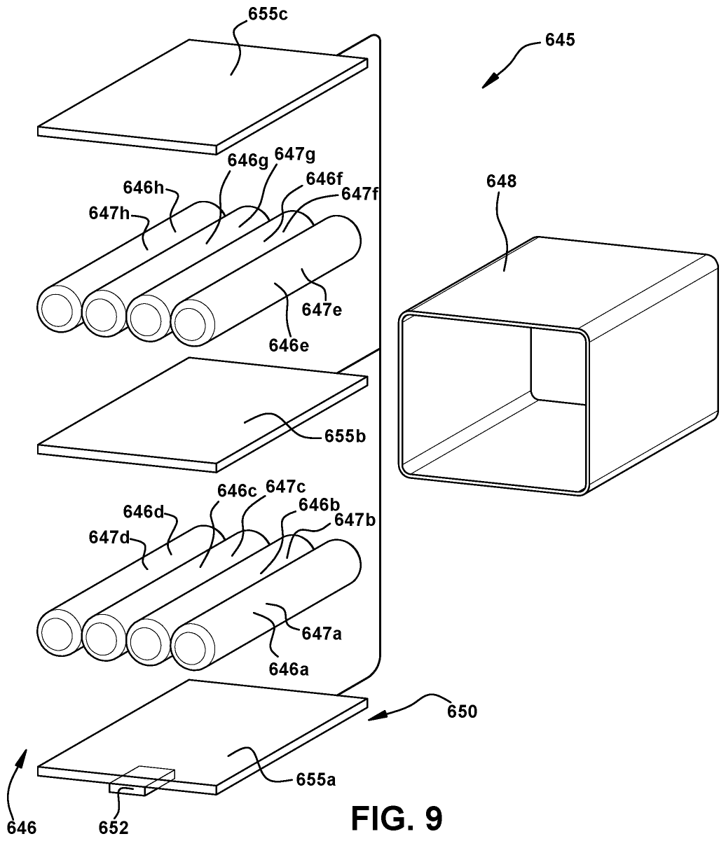

As would be appreciated by one of skill in the art, the battery 645, which in one example embodiment and as schematically depicted in FIG. 9, comprises a battery pack 646 of eight cylindrical battery cells 646a, 646b, 646c, 646d, 646e, 646f, 646g, 646h electrically coupled in series has a significant thermal mass. In one example embodiment, each of the cylindrical battery cells is approximately 1 inch in diameter and 1.5 inches in length, similar in size to a typically Cor D size battery. The eight cell battery pack 646, in one example embodiment, is mechanically bound together by an overlying shrink-wrap plastic material 648 which holds the battery cells 646a, 646b, 646c, 646d, 646e, 646f, 646g, 646h in a rectangular configuration. Accordingly, when the battery 645 is heated by the heating assembly 650, the heating is accomplished by contact/close proximity between the thermal or heat conductive layer 655 of the heating assembly 650 and the outer surface 647 of the battery 645 and, more specifically, the heat conductive layer 655 and the outer surfaces 647a, 647b, 647c, 647d, 647e, 647f, 647g, 647h of the eight cylindrical cells 646a, 646b, 646c, 646d, 646e, 646f, 646g, 646h. Because the shrink-wrap plastic material 648 is very thin, for purposes herein, the term “contact” between the heat conductive layer 655 and the battery outer surface 647 will be deemed to occur whether or not the shrink-wrap plastic material 648 is physically interposed between the battery outer surface 647 and the heat conductive layer 655.

When the battery 645 is heated from the outer surface 647 by the heat conductive layer 655, an interior region of the battery 645 and, more specifically, the interior regions of the cylindrical battery cells 646a, 646b, 646c, 646d, 646e, 646f, 646g, 646h, will not be warmed as fast as the exterior surface 647, that is, the portions of the exterior or outer surfaces 647a, 647b, 647c, 647d, 647e, 647f, 647g, 647h of the eight cylindrical cells 646a, 646b, 646c, 646d, 646e, 646f, 646g, 646h in contact with the heat conductive layer 655. It is difficult to say exactly how much of a temperature differential or gradient will exist between the exterior surface 647 and the interior region of the battery as this would depend on the specifics of the battery mass, material, heating level, configuration of the conductive layer 655 with respect to the outer surface, etc. It is possible to have a cold weather condition where the exterior surface 647 of the battery 645 would be a proper operating temperature, for example, for charging the battery during daylight hours. However, because of the temperature differential between the exterior surface 647 and the interior region, the battery 645 may not operate properly to accept a charge.

One way to address the exterior/interior temperature differential issue is to increase an area of contact between the heat conductive layer 655 of the heating assembly 650 and the outer surface 647 of the battery 645 so that the interior region of the battery 645 heats up more quickly because of a greater surface area of the outer surface 647 being heated. One such configuration of the heating assembly 650 having an enlarged heat conductive layer 655 is depicted schematically of FIG. 9. In the heating assembly 650 of FIG. 9, the heat conductive layer 655 comprises three electrically coupled heat conductive layers 655a, 655b, 655c extending from the heating element 652. The first or lower heat conductive layer 655a extends from the heating element 652 and is in contact with lower portions of the outer surfaces 647a, 647b, 647c, 647d of the battery cells 646a, 646b, 646c, 646d. The second or middle heat conductive layer 655b extends from the lower heat conductive layer 655a and is in contact with upper portions of the outer surfaces 647a, 647b, 647c, 647d of the battery cells 646a, 646b, 646c, 646d and is in contact with lower portions of the outer surfaces 647e, 647f, 647g, 647h of the battery cells 646e, 646f, 646g, 646h. The third or upper heat conductive layer 655c extends from the middle heat conductive layer 655b and is in contact with upper portions of the outer surfaces 647e, 647f, 647g, 647h of the battery cells 646e, 646f, 646g, 646h. In one exemplary embodiment, the conductive layers 655a, 655b, 655c each comprise a set of conductive traces sandwiched between two layers of Kapton® polyimide film, forming a resistive heating element. Advantageously, the Kapton® polyimide film is very durable and will continue to function under adverse environmental circumstances. In the three-part heating conductive layer 655 of the heating assembly 650 of FIG. 9, the thermally conductive material or layer 655 of the heating assembly 650 is configured to increase the area of contact between the layer 655 and the exterior surface 647 of the battery 645. In this manner, the exterior surface 647 of the battery 645 will be heated more quickly and, as a result, the interior region will be also heated more quickly, even with the existence of the temperature differential.

Of course, as would be appreciated by one of skill in the art, other advantageous configurations of the conductive layer 655 are certainly possible and within the scope of the present disclosure. By way of example and without limitation, a lower cost version of the heating assembly 650 depicted in FIG. 9 would be a configuration that includes only the second or middle heat conductive layer 655b extending from the heating element 652. This configuration eliminates the first, lower heat conductive layer 655a and the third, upper heat conductive layer 655b. In this configuration, cost savings is realized from the use of a single conductive layer 655b and, at the same time, enhanced heating of the interior regions of the battery cells 646a, 646b, 646c, 646d, 646e, 646f, 646g, 646h occurs. The enhanced heating of the interior regions of the battery cells 646a, 646b, 646c, 646d, 646e, 646f, 646g, 646h occurs because of the central or intermediate location of the single conductive layer 655b between the lower row of four battery cells 646a, 646b, 646c, 646d and the upper row of four battery cells 646e, 646f, 646g, 646h. That is, as can be seen in FIG. 9, the middle heat conductive layer 655b contacts all eight of the battery cells, specifically, the single middle heat conductive layer 655b is in contact with upper portions of the outer surfaces 647a, 647b, 647c, 647d of the lower row battery cells 646a, 646b, 646c, 646d and is simultaneously in contact with lower portions of the outer surfaces 647e, 647f, 647g, 647h of the upper row battery cells 646c, 646f, 646g, 646h.

Other ways to address the exterior/interior temperature differential issue described above include, but are not limited, to the following. First, the predetermined threshold temperatures for one or both of the daylight threshold temperature DTT and the non-daylight threshold temperature NTT could be raised such that the heating process will commence earlier when the battery temperature T begins to fall. For example, the daylight threshold temperature DTT could be set at 5 degrees C., instead of 1 degree C., above the minimum battery operating temperature for charging the battery 645. Similarly, the nighttime threshold temperature NTT could be set at 5 degrees C., instead of 1 degree C., above the minimum battery operating temperature for discharging the battery 645. Second, improve the configuration and/or insulating properties of the insulation layer 670 surrounding the conductive layer 655 of the heating assembly 650. Third, utilize an interrupted heating cycle by the heating assembly 650. For example, during a heating cycle, instead of merely actuating the heating element 652 and leaving it on until the turn-off temperature DTO, NTO is reached, actuating the heating element 652 for some period of time, then deenergizing the heating element 652 for some period of time, and repeating this pattern, so the heat from the conductive layer 655 has a longer time period to be conducted into the interior region of the battery pack 645. Fourth, utilize a lower level of heat during a heating cycle, however, apply the lower level of heat for a longer period of time, again, so that heat from the conductive layer 655 has a longer time period to be conducted into the interior region of the battery pack 645.

As used herein, terms of orientation and/or direction such as upward, downward, forward, rearward, upper, lower, inward, outward, inwardly, outwardly, horizontal, horizontally, vertical, vertically, distal, proximal, axially, radially, etc., are provided for convenience purposes and relate generally to the orientation shown in the Figures and/or discussed in the Detailed Description. Such orientation/direction terms are not intended to limit the scope of the present disclosure, this application and the invention or inventions described therein, or the claims appended hereto.

What have been described above are examples of the present disclosure/invention. It is, of course, not possible to describe every conceivable combination of components, assemblies, or methodologies for purposes of describing the present disclosure/invention, but one of ordinary skill in the art will recognize that many further combinations and permutations of the present disclosure/invention are possible. Accordingly, the present disclosure/invention is intended to embrace all such alterations, modifications, and variations that fall within the spirit and scope of the appended claims.

What is claimed is:

1. A solar tracker controller for controlling an angle of inclination of a table of an associated solar tracker assembly, the table including a plurality of photovoltaic modules and the solar tracker assembly including a drive mechanism for pivoting the table through an angle of inclination range, the solar tracker controller comprising:
a) controller electronics including a motor driver controlled by the controller electronics, the motor driver electrically coupled to the drive mechanism of the associated solar tracker assembly and selectively energized by the controller electronics to actuate the drive mechanism and thereby pivot the table of the associated solar tracker assembly;
b) a rechargeable battery for powering controller electronics, the rechargeable battery charged by a controller power source and having a minimum required operating temperature, the rechargeable battery including an outer surface;
c) a heating assembly electrically controlled by the controller electronics, the heating assembly disposed in proximity to the outer surface of the rechargeable battery; and
d) a temperature sensor electrically coupled to the controller electronics, the temperature sensor disposed in proximity to the rechargeable battery, the controller electronics monitoring an output signal of the temperature sensor indicative of the temperature of the rechargeable battery and, when the temperature of the rechargeable battery is within a predetermined value of the minimum required operating temperature, the controller electronics actuating the heating assembly to provide heat to the rechargeable battery to maintain the temperature of the rechargeable battery at or above the minimum required operating temperature of the rechargeable battery.

2. The solar tracker controller of claim 1 wherein the one or more photovoltaic modules of the controller power source includes one or more photovoltaic modules mounted to the table of the associated solar tracker assembly.

3. The solar tracker controller of claim 1 wherein the one or more photovoltaic modules of the controller power source includes a string of electrically coupled photovoltaic modules of the plurality of photovoltaic modules of the table of the associated solar tracker assembly.

4. The solar tracker controller of claim 1 further including insulation surrounding at least a portion of an outer surface of the rechargeable battery, the heating element disposed between the insulation and a first portion of the outer surface of the rechargeable battery and the temperature sensor disposed between the insulation and a second portion of the outer surface of the rechargeable battery, the first portion of the outer surface being space from the second portion of the outer surface.

5. The solar tracker controller of claim 1 wherein the controller electronics, the rechargeable battery, the heating element and the temperature sensor are disposed in a controller housing mounted to the table of the associated solar tracker assembly.

6. The solar tracker controller of claim 1 wherein the controller electronics are mounted in a controller housing and the rechargeable battery, the heating element and the temperature sensor are disposed in a battery housing.

7. The solar tracker controller of claim 1 wherein the heating assembly includes a thermally conductive material surrounding at least a portion of the outer surface of the rechargeable battery.

8. The solar tracker controller of claim 1 wherein the controller electronics includes a microcontroller, the microcontroller controlling the motor driver, the heating assembly and the temperature sensor.

9. The solar tracker controller of claim 1 wherein the solar tracker controller includes a second microcontroller, the second microcontroller controlling the heating assembly and the temperature sensor.

10. The solar tracker controller of claim 1 wherein the controller electronics actuates the heating assembly to selectively provide heat to the rechargeable battery to maintain the temperature of the rechargeable battery within a predetermined range at or above the minimum required operating temperature of the rechargeable battery.

11. The solar tracker controller of claim 1 wherein the minimum required operating temperature of the rechargeable battery includes a first minimum required operating temperature during daylight hours to enable charging the rechargeable battery and a second minimum required operating temperature during non-daylight hours to enable discharging the rechargeable battery, the first minimum required operating temperature being greater than the second minimum required operating temperature.

12. The solar tracker controller of claim 11 wherein the first minimum required operating temperature of the rechargeable battery is +2 degrees C. and the second minimum required operating temperature is −8 degrees C.

13. A solar tracker assembly comprising:
a) a table including a plurality of photovoltaic modules and a drive mechanism for pivoting the table through an angle of inclination; and
b) a solar tracker controller for controlling an angle of inclination of the table, the solar tracker controller including:
1) controller electronics including a motor driver controlled by the controller electronics, the motor driver electrically coupled to the drive mechanism of the associated solar tracker assembly and selectively energized by the controller electronics to actuate the drive mechanism and thereby pivot the table of the associated solar tracker assembly;
2) a rechargeable battery for powering controller electronics, the rechargeable battery charged by a controller power source and having a minimum required operating temperature, the rechargeable battery including an outer surface;
3) a heating assembly electrically controlled by the controller electronics, the heating assembly disposed in proximity to the outer surface of the rechargeable battery; and
4) a temperature sensor electrically coupled to the controller electronics, the temperature sensor disposed in proximity to the rechargeable battery, the controller electronics monitoring an output signal of the temperature sensor indicative of the temperature of the rechargeable battery and, when the temperature of the rechargeable battery is within a predetermined value of the minimum required operating temperature, the controller electronics selectively actuating the heating assembly to provide heat to the rechargeable battery to maintain the temperature of the rechargeable battery at or above the minimum required operating temperature of the rechargeable battery.

14. The solar tracker assembly of claim 13 wherein the controller power source includes one or more photovoltaic modules mounted to the table of the solar tracker assembly.

15. The solar tracker assembly of claim 13 wherein the one or more photovoltaic modules of the controller power source of the solar tracker controller includes a string of electrically coupled photovoltaic modules of the plurality of photovoltaic modules of the table of solar tracker assembly.

16. The solar tracker assembly of claim 13 further including insulation surrounding at least a portion of an outer surface of the rechargeable battery of the solar tracker controller, the heating element disposed between the insulation and a first portion of the outer surface of the rechargeable battery and the temperature sensor disposed between the insulation and a second portion of the outer surface of the rechargeable battery, the first portion of the outer surface being space from the second portion of the outer surface.

17. The solar tracker assembly of claim 13 wherein the controller electronics, the rechargeable battery, the heating element and the temperature sensor of the solar tracker controller are disposed in a controller housing mounted to the table of the associated solar tracker assembly.

18. The solar tracker assembly of claim 13 wherein the controller electronics of the solar tracker controller are mounted in a controller housing and the rechargeable battery, the heating element and the temperature sensor of the solar tracker controller are disposed in a battery housing.

19. The solar tracker assembly of claim 13 wherein the heating element of the solar tracker controller includes a thermally conductive material surrounding at least a portion of the outer surface of the rechargeable battery.

20. The solar tracker assembly of claim 13 wherein the controller electronics of the solar tracker controller includes a microcontroller, the microcontroller controlling the motor driver.

21. The solar tracker assembly of claim 13 wherein the solar tracker controller includes a second microcontroller, the second microcontroller controlling the heating assembly and the temperature sensor.

22. The solar tracker assembly of claim 13 wherein the controller electronics of the solar tracker controller actuates the heating assembly to selectively provide heat to the rechargeable battery to maintain the temperature of the rechargeable battery within a predetermined range at or above the minimum required operating temperature of the rechargeable battery.

23. The solar tracker assembly of claim 13 wherein the minimum required operating temperature of the rechargeable battery includes a first minimum required operating temperature during daylight hours to enable charging the rechargeable battery and a second minimum required operating temperature during non-daylight hours to enable discharging the rechargeable battery, the first minimum required operating temperature being greater than the second minimum required operating temperature.

24. The solar tracker assembly of claim 23 wherein the first minimum required operating temperature of the rechargeable battery is +2 degrees C. and the second minimum required operating temperature is −8 degrees C.

25. The solar tracker assembly of claim 14 wherein the one or more photovoltaic modules of the controller power source includes one or more dedicated photovoltaic modules mounted to the table of the solar tracker assembly.
